(19) United States
(12) Patent Application Publication
(10) Pub. No.: US 2025/0155608 A1
(43) Pub. Date: May 15, 2025

(54) PATTERNED SUBSTRATE

(71) Applicant: CORNING INCORPORATED, CORNING, NY (US)

(72) Inventors: Qiumei Bian, Painted Post, NY (US); Charles Brandenburg, Wellsboro, PA (US); Paulo Clovis Dainese, JR., Painted Post, NY (US); Ellen Marie Kosik Williams, Painted Post, NY (US); Shenping Li, Painted Post, NY (US); Jianwei Liu, Painted Post, NY (US); Louis Marra, Corning, NY (US); Cameron Robert Nelson, Oak Park, CA (US); Bin Wang, Painted Post, NY (US); Siavash Yazdanfar, Corning, NY (US)

(21) Appl. No.: 18/933,542

(22) Filed: Oct. 31, 2024

Related U.S. Application Data
(60) Provisional application No. 63/547,921, filed on Nov. 9, 2023.

(51) Int. Cl. G02B 1/12; G02B 27/12

(52) U.S. Cl. CPC G02B 1/12; G02B 27/12

(57) ABSTRACT

A patterned substrate includes a substrate that includes a plurality of laser-ablated areas thereon arranged in the shape of a pattern. The laser-ablated areas each include a nanomaterial therein. Non-laser-ablated areas on the substrate have a lower concentration of the nanomaterial than the laser-ablated areas.

### CROSS-REFERENCE TO RELATED APPLICATIONS

This application claims the benefit of U.S. Provisional Application Ser. No. 63/547,921, filed on Nov. 9, 2023, the content of which is relied upon and incorporated herein by reference in its entirety.

### BACKGROUND

Patterned substrates including micro- or nanopatterns have various applications including diffractive optical elements which can be used for extended reality (XR) applications, such as augmented reality (AR), mixed reality (MR), and virtual reality (VR). Many technologies have been developed to produce such patterned substrates, such as e-beam lithography, photolithography, and nanoimprinting lithography, which involve complex and multistep processes as well as expensive equipment. Also, these techniques are not suitable and flexible for fabricating multi-dimensional patterned surfaces.

Beam splitters are optical components which can divide a beam into two or more beams with various transmission directions according to power, polarization state, or wavelength. Beam splitters are widely used in optical communications, interferometry, multiplexing, spectroscopy, and quantum optics. Conventional beam splitters come into various types or designs such as cube, hexagon, pentagon, polarizing, and plate beam splitters, which are bulky and heavy, restraining their applications in photonics integration and miniaturization.

### SUMMARY OF THE INVENTION

Various aspects of the present invention provide a patterned substrate including a substrate including a plurality of laser-ablated areas thereon arranged in the shape of a pattern. The laser-ablated areas each include a nanomaterial therein. Non-laser-ablated areas on the substrate have a lower concentration of the nanomaterial than the laser-ablated areas.

Various aspects of the present invention provide a patterned optical substrate that includes a glass substrate that includes a plurality of laser-ablated areas thereon arranged in the shape of a periodic pattern and having a spacing therebetween of 1 micron to 20 microns. The laser-ablated areas each include a pit in the substrate. The pit includes a nanomaterial therein. Non-laser-ablated areas on the substrate have a lower concentration of the nanomaterial than the laser-ablated areas. The pit includes the nanomaterial coated around inner edges of the pit such that the nanomaterial decreases the diameter of the laser-ablated pit. The pit including the nanomaterial therein has a diameter of 1 micron to 50 microns.

Various aspects of the present invention provide a method of making a patterned substrate. The method includes laser-ablating a substrate to form a pattern thereon including a plurality of laser-ablated areas. The method also includes exposing the substrate to a nanomaterial precursor to grow a nanomaterial in each laser-ablated area, to form the patterned substrate. Non-laser-ablated areas on the substrate have a lower concentration of the nanomaterial than the laser-ablated areas.

Various aspects of the present invention provide a method of making a patterned substrate. The method includes exposing a substrate including a plurality of laser-ablated areas arranged in the shape of a pattern to a nanomaterial precursor to grow a nanomaterial in each laser-ablated area, to form the patterned substrate. Non-laser-ablated areas on the substrate have a lower concentration of the nanomaterial than the laser-ablated areas.

Various aspects of the present invention provide a method of making a patterned substrate. The method includes exposing a substrate including a plurality of laser-ablated areas arranged in the shape of a pattern, each laser-ablated area including a pit, to a nanomaterial precursor to grow a nanomaterial in each pit, to form the patterned substrate. Non-laser-ablated areas on the substrate have a lower concentration of the nanomaterial than the laser-ablated areas.

Various aspects of the present invention provide a method of making a patterned substrate. The method includes spin-coating a substrate including a plurality of laser-ablated areas arranged in the shape of a pattern, each laser-ablated area including a pit, with a solution including a nanomaterial precursor. The method includes thermally treating the spin-coated laser-ablated substrate to grow the nanomaterial in the pit of each laser-ablated area, to form the patterned substrate. Non-laser-ablated areas on the substrate have a lower concentration of the nanomaterial than the laser-ablated areas.

Various aspects of the present invention provide a method of making a patterned substrate. The method includes immersing a substrate including plurality of laser-ablated areas arranged in the shape of a pattern, each laser-ablated area including a pit, with a solution including a nanoparticle precursor, to grow the nanomaterial in the pit of each laser-ablated area, to form the patterned substrate. Non-laser-ablated areas on the substrate have a lower concentration of the nanomaterial than the laser-ablated areas.

Various aspects of the present invention provide a method of making a patterned substrate. The method includes laser-ablating a glass substrate to form a pattern thereon including a plurality of laser-ablated areas, each laser-ablated area including a pit. The method also includes thermally treating the laser-ablated substrate and a nanoparticle precursor including a material produced during the laser-ablating of the substrate to grow a nanomaterial including SiO₂ in the pit of each laser-ablated area, to form the patterned substrate. Non-laser-ablated areas on the substrate have a lower concentration of the nanomaterial than the laser-ablated areas.

Various aspects of the patterned substrate of the present invention and method of making the same have various advantages over conventional patterned substrates and methods of making the same. For example, in various aspects, the present invention provides a method of forming a patterned substrate that avoids photolithography and nanoimprint technologies, which involve complex processing and expensive equipment. In various aspects, the patterned substrate of the present invention can have superior mechanical properties as compared to optical devices formed using photolithography or nanoimprint techniques.

In various aspects, the patterned substrate of the present invention can be optically transparent and can be used for diffractive optical elements, extended reality devices, beam splitters, and other optical devices. In various aspects, the method of forming a patterned substrate of the present invention can be easily controlled and/or tuned to vary and control the properties of the resulting patterned substrate. Examples of diffractive optical elements include optical devices that change the phase of light propagated therethrough such as diffractive optical waveguides, beam splitters, and diffractive diffusers for optical sensors, optical distance and speed measurement systems, fiber coupling, and laser display and illumination systems.

In various aspects, the patterned substrate of the present invention can be a beam splitter. Extensive efforts have recently been made to develop micro-nano photonics—ultra-thin artificial materials to replace traditional thick optical structures for beam splitters with a small size, easy integration, and high efficiency. In various aspects, the patterned substrate of the present invention can replace traditional thick optical structures for beam splitters, and can have a thinner and lighter profile while still providing flexible and effective manipulation of light for beam splitters. Beam splitters are widely used in optical communication, interferometer, multiplexing, spectroscopy, and quantum optics. In various aspects, the beam splitter of the present invention can be used for large-scale photonic integrated applications.

### BRIEF DESCRIPTION OF THE FIGURES

The drawings illustrate generally, by way of example, but not by way of limitation, various aspects of the present invention.

FIG. 1A illustrates a side view of clean substrate, in accordance with various aspects.

FIG. 1B illustrates a side view of a substrate patterned with a micropattern using a laser, in accordance with various aspects.

FIG. 1C illustrates a side view of a micropatterned substrate including nanoparticles deposited thereon, in accordance with various aspects.

FIG. 1D illustrates a top view of the micropatterned substrate shown in FIG. 1B, in accordance with various aspects.

FIG. 1E illustrates a top view close-up of a micropatterned area from FIG. 1C, showing nanoparticles within the micropattern, in accordance with various aspects.

FIG. 2 illustrates a SEM image of a periodic micropattern on glass formed using a laser with 30% power at 1 W, in accordance with various aspects.

FIG. 3 illustrates a SEM image of the periodic micropattern on glass shown in FIG. 2 having ZrO₂ nanoparticles deposited thereon, in accordance with various aspects.

FIG. 4A illustrates a SEM image of a periodic micropattern on glass formed using a laser with 20% power at 1 W, in accordance with various aspects.

FIG. 4B illustrates a SEM image of the periodic micropattern on glass shown in FIG. 4A having ZnO nanoparticles deposited thereon, in accordance with various aspects.

FIG. 5A illustrates a 3D transmission spectrum of micropatterned glass including deposited ZnO nanoparticles measured with 520 nm incident angle, in accordance with various aspects.

FIG. 5B illustrates a 2D transmission spectrum of micropatterned glass including deposited ZnO nanoparticles measured with 520 nm incident angle, in accordance with various aspects.

FIG. 6A illustrates a side view of a clean glass substrate, in accordance with various aspects.

FIG. 6B illustrates a side view of a micropattern gradient structure on a substrate formed by laser ablation, in accordance with various aspects.

FIG. 6C illustrates a side view of the micropattern gradient structure shown in FIG. 6B after thermal treatment, in accordance with various aspects.

FIG. 6D illustrates a top view of the thermally treated micropattern gradient structure shown in FIG. 6B, in accordance with various aspects.

FIG. 7A illustrates a SEM image of a micropattern gradient structure formed on glass using laser ablation and thermal treatment, in accordance with various aspects.

FIG. 7B illustrates a high-resolution SEM image of the micropattern gradient structure shown in FIG. 7A, with the overlaid square illustrating the pitch of the micropattern, in accordance with various aspects.

FIG. 8A illustrates a 3D interferometer image of a micropattern gradient structure on glass, in accordance with various aspects.

FIG. 8B illustrates a 2D top view interferometer image of the micropattern gradient structure shown in FIG. 8A, in accordance with various aspects.

FIG. 9A illustrates an intensity image of interferometer data of a micropattern gradient structure on glass, in accordance with various aspects.

FIG. 9B illustrates the profile of a 2D slide through micropattern gradient area of a micropattern gradient structure on glass, in accordance with various aspects.

FIG. 10A illustrates equipment used to measure optical diffraction pattern spectra of a sample, in accordance with various aspects.

FIG. 10B illustrates an angle of split beam formed during optical diffraction pattern measurement of a sample, in accordance with various aspects.

FIG. 10C shows the optical diffraction pattern spectrum of a sample measured with 1480 to 1640 nm incident, in accordance with various aspects.

FIG. 11A illustrates a phase profile of a micropattern gradient structure on glass measured using off-axis digital holography, in accordance with various aspects.

FIG. 11B illustrates a phase cut of a phase profile of a micropattern gradient structure on glass measured using off-axis digital holography, in accordance with various aspects.

FIG. 12 illustrates plot showing bidirectional scattering distribution function (BSDF) versus scatting angle (degrees) for two glass substrates laser treated at the same scanning rate but with different laser power, in accordance with various aspects.

### DETAILED DESCRIPTION OF THE INVENTION

Reference will now be made in detail to certain aspects of the disclosed subject matter. While the disclosed subject matter will be described in conjunction with the enumerated claims, it will be understood that the exemplified subject matter is not intended to limit the claims to the disclosed subject matter.

Throughout this document, values expressed in a range format should be interpreted in a flexible manner to include not only the numerical values explicitly recited as the limits of the range, but also to include all the individual numerical values or sub-ranges encompassed within that range as if each numerical value and sub-range is explicitly recited. For example, a range of “about 0.1% to about 5%” or “about 0.1% to 5%” should be interpreted to include not just about 0.1% to about 5%, but also the individual values (e.g., 1%, 2%, 3%, and 4%) and the sub-ranges (e.g., 0.1% to 0.5%, 1.1% to 2.2%, 3.3% to 4.4%) within the indicated range. The statement “about X to Y” has the same meaning as “about X to about Y,” unless indicated otherwise. Likewise, the statement “about X, Y, or about Z” has the same meaning as “about X, about Y, or about Z,” unless indicated otherwise.

In this document, the terms “a,” “an,” or “the” are used to include one or more than one unless the context clearly dictates otherwise. The term “or” is used to refer to a nonexclusive “or” unless otherwise indicated. The statement “at least one of A and B” or “at least one of A or B” has the same meaning as “A, B, or A and B.” In addition, it is to be understood that the phraseology or terminology employed herein, and not otherwise defined, is for the purpose of description only and not of limitation. Any use of section headings is intended to aid reading of the document and is not to be interpreted as limiting; information that is relevant to a section heading may occur within or outside of that particular section.

In the methods described herein, the acts can be carried out in a specific order as recited herein. Alternatively, in any aspect(s) disclosed herein, specific acts may be carried out in any order without departing from the principles of the invention, except when a temporal or operational sequence is explicitly recited. Furthermore, specified acts can be carried out concurrently unless explicit claim language recites that they be carried out separately or the plain meaning of the claims would require it. For example, a claimed act of doing X and a claimed act of doing Y can be conducted simultaneously within a single operation, and the resulting process will fall within the literal scope of the claimed process.

The term “about” as used herein can allow for a degree of variability in a value or range, for example, within 10%, within 5%, or within 1% of a stated value or of a stated limit of a range, and includes the exact stated value or range.

The term “substantially” as used herein refers to a majority of, or mostly, as in at least about 50%, 60%, 70%, 80%, 90%, 95%, 96%, 97%, 98%, 99%, 99.5%, 99.9%, 99.99%, or at least about 99.999% or more, or 100%. The term “substantially free of” as used herein can mean having none or having a trivial amount of, such that the amount of material present does not affect the material properties of the composition including the material, such that about 0 wt % to about 5 wt % of the composition is the material, or about 0 wt % to about 1 wt %, or about 5 wt % or less, or less than, equal to, or greater than about 4.5 wt %, 4, 3.5, 3, 2.5, 2, 1.5, 1, 0.9, 0.8, 0.7, 0.6, 0.5, 0.4, 0.3, 0.2, 0.1, 0.01, or about 0.001 wt % or less, or about 0 wt %.

### Patterned Substrate.

In various aspects the present invention provides a patterned substrate. The patterned substrate includes a substrate that includes a plurality of laser-ablated areas thereon. The laser-ablated areas are arranged in the shape of a pattern on the substrate. The laser-ablated areas each include a nanomaterial therein. Non-laser-ablated areas on the substrate can have a lower concentration of the nanomaterial than the laser-ablated areas.

The patterned substrate can be an optical substrate. The patterned substrate can be optically transparent. The patterned substrate on a transparent substrate such as glass provides a platform to change the phase of the light propagated through the patterned substrate.

The patterned substrate can be an optical component of, or can be, a diffractive optical waveguide, a beam splitter, a diffractive diffuser, or a combination thereof. The patterned substrate can be a beam splitter. The patterned substrate can be an optical component of an optical sensor, an optical distance and/or speed measurement system, fiber coupling, a laser display and/or illumination system, an extended reality system, or a combination thereof.

The substrate can include glass, ceramic, silicon, quartz, or a combination thereof. The substrate can be substantially flat.

The laser-ablated areas of the substrate are areas where portions of the substrate have been removed due to treatment with a laser beam. The laser-ablated areas can include heat affected zones adjacent thereto that have not been laser-ablated to the same extent as the laser-ablated areas, but that have experienced heating as a result of the laser treatment. The heat affected zones can be characterized as having a lesser slope than the laser-ablated areas described herein, and have a concentration of the nanomaterial that is less than the concentration of the nanomaterial in the laser-ablated areas. The non-laser-ablated areas of the substrate (including the heat affected zones) can be substantially free of the nanomaterial. For example, 50 wt % to 100% of the total amount of the nanomaterial on the substrate can be located in the laser-ablated areas, or 80 wt % to 100 wt %, or 90 wt % to 100 wt %, or 95 wt % to 100 wt %, or less than or equal to 100 wt % and greater than or equal to 50 wt % and less than, equal to, or greater than 55 wt %, 60, 65, 70, 75, 80, 82, 84, 86, 88, 90, 91, 92, 93, 94, 95, 96, 97, 98, 99, 99.9, 99.99, or 99.999 wt %.

The laser-ablated areas can have any suitable shape formed by removal of portions of the substrate via laser treatment. For example, the laser-ablated areas can include a pit, a trench, a polygon, an irregular shape, a line segment, a triangle, or a circle. The laser-ablated areas can each include a pit in the substrate, wherein the pit includes the nanomaterial therein. The pit can have any suitable diameter, such as a diameter of 1 micron to 50 microns, or 1 micron to 10 microns, or 4 microns to 6 microns, or less than or equal to 50 microns and greater than or equal to 1 microns and less than, equal to, or greater than 2 microns, 3, 4, 5, 6, 7, 8, 9, 10, 12, 14, 16, 18, 20, 25, 30, 35, 40, or 45 microns. The pit can have any suitable depth, such as a depth of 0.1 microns to 10 microns, 0.5 microns to 3 microns, or 1.5 microns to 1.8 microns, or less than or equal to 10 microns and greater than or equal to 0.1 microns and less than, equal to, or greater than 0.5 microns, 0.6, 0.8, 1, 1.1, 1.2, 1.3, 1.4, 1.5, 1.6, 1.7, 1.8, 1.9, 2, 2.1, 2.2, 2.3, 2.4, 2.5, 2.6, 2.8, 3, 3.2, 3.4, 3.6, 3.8, 4, 4.5, 5, 6, 7, 8, or 9 microns.

In various aspects, the pattern formed on the substrate by the laser-ablated areas can include a spacing between the laser-ablated areas (e.g., a spacing between centers of the laser-ablated areas) of no more than 100 microns, or of 1 micron to 20 microns, or of less than or equal to 100 microns and greater than or equal to 1 micron and less than, equal to, or greater than 2 microns, 4, 6, 8, 10, 12, 14, 16, 18, 20, 25, 30, 35, 40, 45, 50, 55, 60, 65, 70, 75, 80, 85, 90, or 95 microns. The pattern can be a periodic pattern. The pattern can include a grid, such as a grid formed of a plurality of pits.

The laser-ablated areas include a nanomaterial therein. The nanomaterial can be a coating on the laser-ablated areas. The coating can be on the surface of the laser-ablated areas. The coating can be at least partially embedded in the surface of the laser-ablated areas. The coating can be homogeneous within the laser-ablated areas, or the coating can be heterogeneously or unevenly distributed within the laser-ablated areas. The coating of the nanomaterial in the laser-ablated areas can have a substantially uniform thickness. The coating can have any suitable thickness, such as a thickness of 1 nm to 25 microns, or 1 nm to 1000 nm, or less than or equal to 25 microns and greater than or equal to 1 nm and less than, equal to, or greater than 2 nm, 4, 6, 8, 10, 15, 20, 25, 30, 40, 50, 60, 70, 80, 90, 100, 150, 200, 250, 500, 750, 1 micron, 2, 4, 6, 8, 10, 15, or 20 microns.

The laser-ablated areas can include the nanomaterial coated thereon such that the size (e.g., diameter and/or depth) of the laser-ablated area is decreased due to the nanomaterial thereon. For example, a laser-ablated area that is a pit can include a nanomaterial coating therein that includes nanomaterial coated around inner edges of the pit such that the pit including the nanomaterial therein has a smaller diameter than the pit as originally formed from the laser ablation. A pre-nanomaterial-addition diameter and/or depth of a laser-ablated area can be 1 nm to 25 microns greater than a corresponding diameter and/or depth of the pit including the nanomaterial, or 1 nm to 1000 nm greater, or greater by an amount that is less than or equal to 25 microns and greater than or equal to 1 nm and less than, equal to, or greater than 2 nm, 4, 6, 8, 10, 15, 20, 25, 30, 40, 50, 60, 70, 80, 90, 100, 150, 200, 250, 500, 750, 1 micron, 2, 4, 6, 8, 10, 15, or 20 microns.

The nanomaterial in the laser-ablated areas of the substrate can be any suitable nanomaterial. The nanomaterial can be formed of the same material that forms the substrate, or the nanomaterial can be a different material than the substrate. In various aspects, the nanomaterial can include some nanomaterial that is formed of the same material that forms the substrate, and some nanomaterial that is formed of a different material than the material that forms the substrate. The nanomaterial can include MgO, Fe₂O₃, V₂O₅, Al₂O₃, SiO₂, ZnO, ZrO₂, TiO₂, Ag, Au, Cu, or a combination thereof. The nanomaterial can include SiO₂, ZnO, ZrO₂, TiO₂, or a combination thereof. In various aspects, the nanomaterial can include crystallites, nanoparticles, or a combination thereof. In various aspects, the nanomaterial can consist of crystallites, nanoparticles, or a combination thereof. The nanomaterial can be a nanomaterial that has grown on the laser-ablated areas, such as during a heat-treatment of the laser-ablated surface while the laser-ablated surface is proximate to or contacting the nanomaterial or a nanomaterial precursor. The nanomaterial, crystallites, or nanoparticles can have a diameter or largest particle size of 1 nm to 1,000 nm, or 1 nm to 500 nm, or less than or equal to 1,000 nm and greater than or equal to 1 nm and less than, equal to, or greater than 2 nm, 3, 4, 5, 6, 8, 10, 12, 14, 16, 18, 20, 25, 30, 35, 40, 45, 50, 60, 70, 80, 90, 100, 120, 140, 160, 180, 200, 250, 300, 350, 400, 450, 500, 600, 700, 800, or 900 nm.

### Method of Making a Patterned Substrate.

Various aspects of the present invention provide a method of a patterned substrate. The method can be any suitable method that forms the patterned substrate described herein. For example, the method can include exposing a substrate that includes a plurality of laser-ablated areas arranged in the shape of a pattern thereon to a nanomaterial precursor to grow a nanomaterial in each laser-ablated area, to form the patterned substrate. In various aspects, the method can also include laser-ablating the substrate to form the laser-ablated areas thereon.

The method can include performing the laser ablation. In other aspects, the laser ablation is performed prior to the onset of the method. The laser ablation removes a portion of the substrate to form the laser-ablated areas. The laser ablation can also heat areas adjacent to the laser-ablated areas. The laser-ablated areas can include a pit, a trench, a polygon, an irregular shape, a line segment, a triangle, or a circle. In various aspects, the laser-ablated areas are pits.

The laser used for the laser-ablating can have a beam shape that is gaussian, non-gaussian, multimode, or flat-top. The laser can have a beam shape that is gaussian. The laser can have a wavelength of 180 nm to 10.6 microns, or 200 nm to 2 microns, or 300 nm to 1500 nm, or 355 nm to 1064 nm, or less than or equal to 10.6 microns and greater than or equal to 180 nm and less than, equal to, or greater than 200, 220, 240, 260, 280, 300, 320, 340, 360, 380, 400, 450, 500, 550, 600, 650, 700, 750, 800, 850, 900, 950, 1,000, 1,050, 1,100, 1,200 nm, 1.5 microns, 2, 2.5, 3, 4, 5, 6, 7, 8, 9, or 10 microns.

The laser can be a pulsed laser. The pulsed laser can have a repetition rate of 1 kHz to 10,000 kHz, or 10 kHz to 100 kHz, or less than or equal to 10,000 kHz and greater than or equal to 1 kHz and less than, equal to, or greater than 2 kHz, 4, 6, 8, 10, 20, 30, 40, 50, 60, 70, 80, 90, 100, 200, 500, 750, 1,000, 2,000, 4,000, 6,000, or 8,000 kHz. The pulsed laser can have a power of 0.01 W to 100 W, or 0.1 W to 10 W, or less than or equal to 100 W and greater than or equal to 0.01 W and less than equal to, or greater than 0.05 W, 0.1, 0.5, 1, 2, 3, 4, 5, 6, 7, 8, 9, 10, 12, 14, 16, 18, 20, 25, 30, 35, 40, 45, 50, 60, 70, 80, or 90 W, and can be used at a power of 1% to 100%, or 10% to 80%, or 20% to 50%, or less than or equal to 100% and greater than or equal to 1% and less than, equal to, or greater than 2%, 4, 6, 8, 10, 15, 20, 25, 30, 35, 40, 45, 50, 55, 60, 65, 70, 75, 80, 85, 90, or 95%. The pulsed laser can have an energy of 1 microjoule to 1,000 microjoules, or 5 microjoule to 100 microjoules, or less than or equal to 1,000 microjoules and greater than or equal to 1 microjoule and less than, equal to, or greater than 2 microjoules, 4, 6, 8, 10, 12, 14, 16, 18, 20, 25, 30, 35, 40, 45, 50, 55, 60, 65, 70, 80, 90, 100, 150, 200, 250, 300, 400, 500, 600, 700, 800, or 900 microjoules. When making the laser-ablated areas, the laser can be moved relative to a surface of the substrate at a translation speed of 1 mm/s to 10,000 mm/s, or 500 mm/s to 10,000 mm/s, or less than or equal to 10,000 mm/s and greater than or equal to 1 mm/s and less than, equal to, or greater than 2 mm/s, 4, 6, 8, 10, 15, 20, 25, 30, 35, 40, 45, 50, 60, 70, 80, 90, 100, 150, 200, 250, 300, 350, 400, 450, 500, 600, 700, 800, 900, 1,000, 1,500, 2,000, 3,000, 4,000, 5,000, 6,000, or 8,000 mm/s. The laser can have a beam diameter of 0.5 micron to 100 microns, or 3 microns to 12 microns, or less than or equal to 100 microns and greater than or equal to 0.5 micron and less than, equal to, or greater than 1 micron, 2, 3, 4, 5, 6, 7, 8, 9, 10, 11, 12, 13, 14, 15, 16, 17, 18, 19, 20, 22, 24, 26, 28, 30, 35, 40, 45, 50, 55, 60, 65, 70, 75, 80, 85, 90, or 95 microns.

The exposing of the substrate to the nanomaterial precursor grows the nanomaterial in each laser-ablated area, such as crystallites and/or nanoparticles. The exposing of the substrate to the nanomaterial precursor can include thermally treating (e.g., heating) the laser-ablated substrate in the presence of the nanomaterial precursor to form the patterned substrate. The thermal treatment can include thermally treating at a temperature of 100° C. to 1,000° C., or 200° C. to 600° C., or 350° C. to 500° C., or less than or equal to 1,000° C. and greater than or equal to 100° C. and less than, equal to, or greater than 120° C., 140, 160, 180, 200, 210, 220, 230, 240, 250, 260, 270, 280, 290, 300, 310, 320, 330, 340, 350, 360, 370, 380, 390, 400, 410, 420, 430, 440, 450, 460, 470, 480, 490, 500, 520, 540, 560, 580, 600, 650, 700, 750, 800, 850, 900, or 950° C. The thermal treatment can include thermally treating for a duration of 1 minute to 5 days, or 10 minutes to 1 hour, or less than or equal to 5 days and greater than or equal to 1 minute and less than, equal to, or greater than 2 minutes, 4 minutes, 6 minutes, 8 minutes, 10 minutes, 15 minutes, 20 minutes, 25 minutes, 30 minutes, 35 minutes, 40 minutes, 45 minutes, 50 minutes, 55 minutes, 1 h, 1.2 h, 1.4 h, 1.5 h, 1.6 h, 1.8 h, 2 h, 2.5 h, 3 h, 4 h, 5 h, 6 h, 8 h, 10 h, 12 h, 14 h, 16 h, 18 h, 20 h, 22 h 1 days, 1.5 d, 2 d, 3 d, or 4 days.

The nanomaterial precursor can be any suitable nanomaterial precursor that forms the nanomaterial. The nanomaterial precursor can include a material that is added to the laser-ablated substrate, a material produced by laser-ablating of the substrate, or a combination thereof.

The nanomaterial precursor can include a material that is added to the laser-ablated substrate. For example, the nanomaterial precursor can include a solution that forms the nanomaterial. In various aspects, the solution includes a zinc salt, and the nanomaterial includes ZnO. The nanomaterial precursor can include a solution that includes ZrO₂. The nanomaterial precursor can include a solution that includes MgO, Fe₂O₃, V₂O₅, Al₂O₃, SiO₂, ZnO, ZrO₂, TiO₂, Ag, Au, Cu, or a Mg salt, an Fe salt, a V salt, an Al salt, a Zn salt, a Zr salt, a Ti salt, an Ag salt, an Au salt, a Cu salt, or a combination thereof. The exposing of the substrate to the nanomaterial precursor can include adding the nanomaterial precursor to the laser-ablated substrate, and thermally treating the laser-ablated substrate having the nanomaterial precursor added thereto. The exposing the substrate to the nanomaterial precursor can include spin-coating a solution of the nanomaterial precursor on the laser-ablated substrate, and thermally treating the spin-coated laser-ablated substrate. The exposing the substrate to the nanomaterial precursor can include immersing the laser-ablated substrate in a solution including the nanomaterial precursor. The immersing can be performed at any suitable temperature, such as a temperature of 0° C. to 100° C., or 60° C. to 100° C., or less than or equal to 100° C. and greater than or equal to 0° C. and less than, equal to, or greater than 10° C., 20, 30, 40, 50, 55, 60, 65, 70, 75, 80, 85, 90, or 95° C. The immersing can be performed for a duration of 1 minute to 5 days, or 10 minutes to 1 hour, or less than or equal to 5 days and greater than or equal to 1 minute and less than, equal to, or greater than 2 minutes, 4 minutes, 6 minutes, 8 minutes, 10 minutes, 15 minutes, 20 minutes, 25 minutes, 30 minutes, 35 minutes, 40 minutes, 45 minutes, 50 minutes, 55 minutes, 1 h, 1.2 h, 1.4 h, 1.5 h, 1.6 h, 1.8 h, 2 h, 2.5 h, 3 h, 4 h, 5 h, 6 h, 8 h, 10 h, 12 h, 14 h, 16 h, 18 h, 20 h, 22 h 1 days, 1.5 d, 2 d, 3 d, or 4 days.

The nanomaterial precursor can include a material produced by laser-ablating of the substrate. For example, the nanomaterial precursor can include SiO₂ formed by laser ablation of a glass substrate. The exposing of the substrate to the nanomaterial precursor can include thermally treating the laser-ablated substrate having the nanomaterial precursor formed by laser-ablating of the substrate thereon. The thermal treatment can quench the nanomaterial precursor that is generated by the laser ablation, to form the patterned substrate.

### EXAMPLES

Various aspects of the present invention can be better understood by reference to the following Examples which are offered by way of illustration. The present invention is not limited to the Examples given herein.

### Example 1. Deposition of ZrO₂ Nanoparticles on Periodic Micropattern on Glass

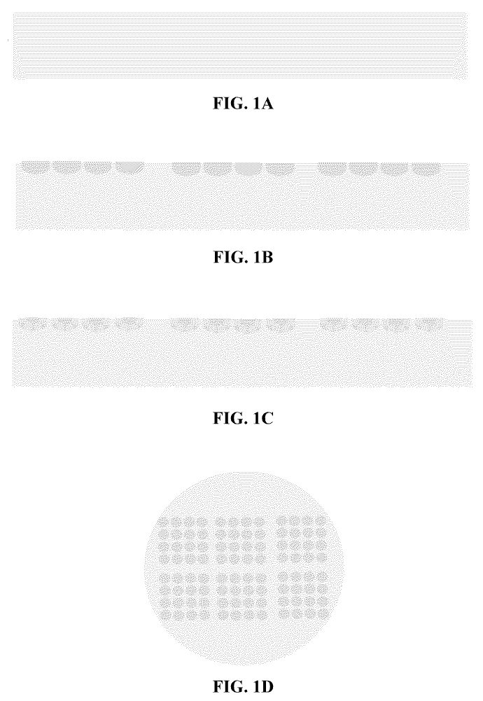

The designing and fabrication processes are illustrated in FIG. 1. The clean glass (FIG. 1A) was patterned using a laser to form a micropattern structure (FIG. 1B). Nanomaterials were deposited on the micropattern glass. FIG. 1D shows the top view of the micropattern glass. As a result of the nanomaterials deposition, nanostructure materials are be coated or deposited on a micro-pattern area, as shown in FIG. 1E.

The laser patterning was performed at room temperature using a UV and green laser as a gaussian beam having a diameter of 3 microns to 12 microns, a wavelength of 355-532 nm, an energy of 10-50 microjoules, a scanning speed of 50-3,000 mm/s, a repetition rate of 10-100 kHz, and a laser power of 0.1-5 W.

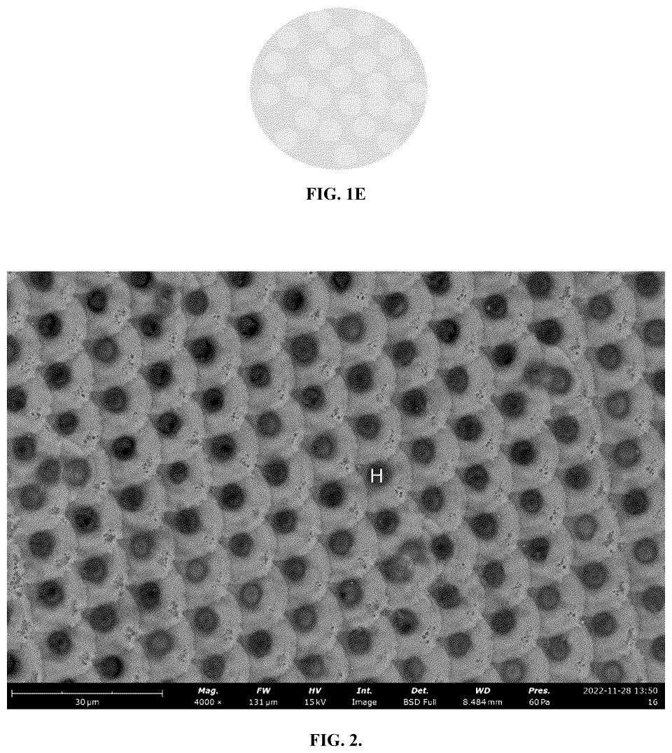

After laser patterning at 20% power at 1 W, a periodic micro hole array can be observed, as shown in FIG. 2. The diameter of the holes is 5 micrometers (a hole in FIG. 2 is overlaid with the label “H”), and the distance between centers of holes is 10 micrometers. The diameter and distance can be tuned by controlling laser power and stage feeding speed.

A ZrO₂ solution was spin-coated on a laser-patterned glass surface formed using laser power of 30% at 1 W to a thickness of 500 nm. The spin-coated patterned glass surface was then subjected to a thermal treatment by placing in an oven at 200° C. for 30 minutes.

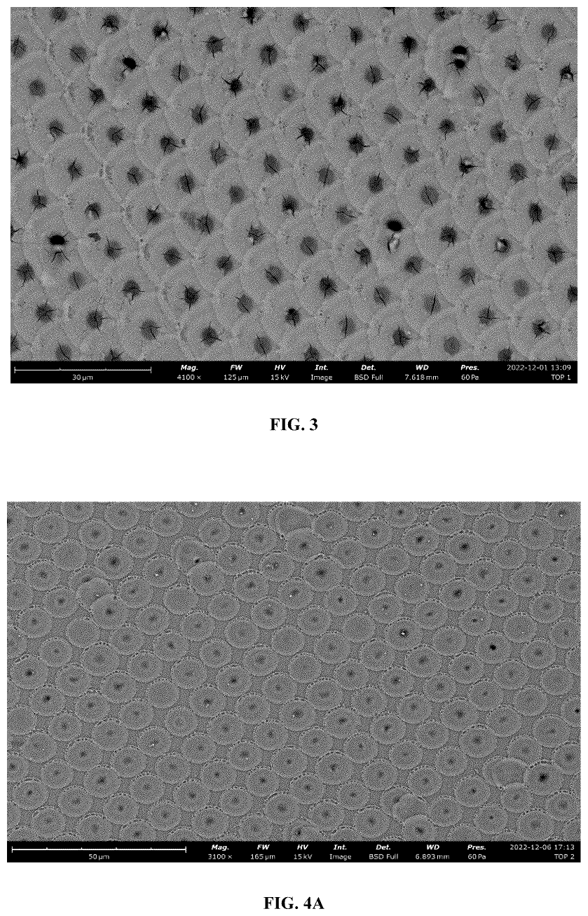

After depositing ZrO₂ nanoparticles, the nanoparticles could be observed around edges of the holes, resulting in a decrease of the diameters of the holes shown in FIG. 3. Also, EDS data further confirms ZrO₂ nanoparticles deposition on periodic micro-pattern glasses. Tables 1-4 display EDS data on periodic micro-pattern glass and ZrO₂ nanoparticles on micro-pattern glass on the hole area and off the hole area. The atomic concentration of zirconium (Zr) on the hole area increased from 1.930% to 16.857% after ZrO₂ nanoparticles deposition, indicating ZrO₂ nanoparticles around the inside of the holes. In addition, the atomic concentration of zirconium (Zr) off hole area slightly increased, demonstrating small amount of ZrO₂ nanoparticles deposited off the hole area.

TABLE 1
EDS of on-hole area of micropattern before
depositing ZrO₂ microparticles.

| Element | Element | Element | Atomic | Weight |
|---|---|---|---|---|
| number | symbol | name | conc. | conc. |
| 8 | O | Oxygen | 75.174 | 40.340 |
| 14 | Si | Silicon | 3.613 | 3.403 |
| 20 | Ca | Calcium | 7.074 | 9.510 |
| 22 | Ti | Titanium | 2.804 | 4.505 |
| 40 | Zr | Zirconium | 1.930 | 5.906 |
| 41 | Nb | Niobium | 4.851 | 15.115 |
| 57 | La | Lanthanum | 4.555 | 21.221 |

TABLE 2
EDS of off-hole area of micropattern before depositing ZrO₂.

| Element | Element | Element | Atomic | Weight |
|---|---|---|---|---|
| number | symbol | name | conc. | conc. |
| 8 | O | Oxygen | 77.763 | 43.844 |
| 14 | Si | Silicon | 3.236 | 3.203 |
| 20 | Ca | Calcium | 6.237 | 8.809 |
| 22 | Ti | Titanium | 2.609 | 4.404 |
| 40 | Zr | Zirconium | 1.775 | 5.706 |
| 41 | Nb | Niobium | 4.311 | 14.114 |
| 57 | La | Lanthanum | 4.069 | 19.920 |

TABLE 3
EDS ot on-hole area of micropattern atter depositing Zro2.

| Element | Element | Element | Atomic | Weight |
|---|---|---|---|---|
| number | symbol | name | conc. | conc. |
| 8 | O | Oxygen | 60.112 | 22.900 |
| 14 | Si | Silicon | 2.542 | 1.700 |
| 20 | Ca | Calcium | 7.545 | 7.200 |
| 22 | Ti | Titanium | 3.332 | 3.800 |
| 40 | Zr | Zirconium | 16.852 | 36.600 |
| 41 | Nb | Niobium | 3.662 | 8.100 |
| 57 | La | Lanthanum | 5.956 | 19.700 |

TABLE 4
EDS of off-hole area of micropattern after depositing ZrO₂.

| Element | Element | | Atomic | Weight |
|---|---|---|---|---|
| number | symbol | Element name | conc. | conc. |
| 8 | O | Oxygen | 73.133 | 37.000 |
| 14 | Si | Silicon | 3.603 | 3.200 |
| 20 | Ca | Calcium | 6.470 | 8.200 |
| 22 | Ti | Titanium | 2.641 | 4.000 |
| 40 | Zr | Zirconium | 5.096 | 14.700 |
| 41 | Nb | Niobium | 4.731 | 13.900 |
| 57 | La | Lanthanum | 4.325 | 19.000 |

### Example 2. Deposition of ZnO Nanoparticles on Periodic Micropattern on Glass

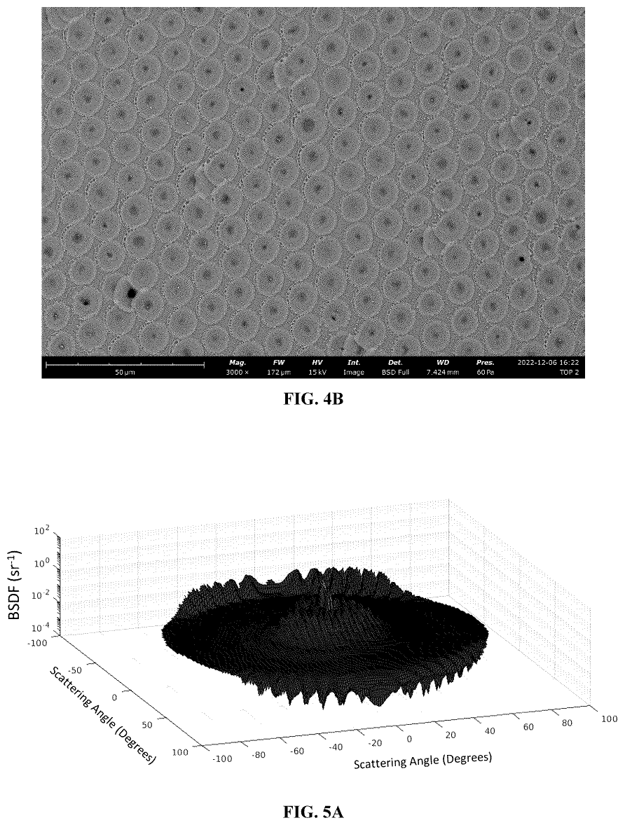

In addition, laser conditions were controlled to tune micropattern morphology and structure as well as pitches. The conditions for the laser treatment were otherwise the same as described in Example 1, but the power of the laser was reduced to 20% at 1 W. FIG. 4A shows periodic micropattern after applying lower laser power. Periodic nanostructures of ZnO were grown on glass, as shown in FIG. 4B. The ZnO nanoparticles were grown by immersing the laser-treated surface at 80° C. for 30 minutes in an aqueous solution (pH 10-11) that included zinc chloride and ammonium hydroxide. The EDS data of the micropatterned glass for on-hole and off-hole area before and after ZnO deposition are given in Tables 5-8. The atomic concentration of zinc (Zn) on hole area increased to 0.799 after ZnO nanoparticles growth, indicating ZnO nanoparticles in the hole areas. In addition, in the EDS for off-hole area of the micropattern after depositing ZnO, the atomic Zn couldn't be detected, demonstrating no ZnO was grown off the hole area. The ZnO selectively grew in the hole areas generated by laser due to the nucleation of ZnO crystallites directly on defects of glass generated by the laser served as nucleation sites for ZnO growth.

Table 5. EDS of on-hole area of micropattern before depositing ZnO.

TABLE 5
EDS of on-hole area of micropattern before depositing ZnO.

| Element | Element | Element | Atomic | Weight |
|---|---|---|---|---|
| number | symbol | name | conc. | conc. |
| 8 | O | Oxygen | 77.252 | 43.043 |
| 14 | Si | Silicon | 3.275 | 3.203 |
| 20 | Ca | Calcium | 6.383 | 8.909 |
| 22 | Ti | Titanium | 2.640 | 4.404 |
| 40 | Zr | Zirconium | 1.702 | 5.405 |
| 41 | Nb | Niobium | 4.548 | 14.715 |
| 57 | La | Lanthanum | 4.200 | 20.320 |

TABLE 6
EDS of off-hole area of micropattern before depositing ZnO.

| Element | Element | Element | Atomic | Weight |
|---|---|---|---|---|
| number | symbol | name | conc. | conc. |
| 8 | O | Oxygen | 73.841 | 38.661 |
| 14 | Si | Silicon | 3.695 | 3.397 |
| 20 | Ca | Calcium | 7.541 | 9.890 |
| 22 | Ti | Titanium | 2.932 | 4.595 |
| 40 | Zr | Zirconium | 2.075 | 6.194 |
| 41 | Nb | Niobium | 5.192 | 15.784 |
| 57 | La | Lanthanum | 4.725 | 21.479 |

TABLE 7
EDS of on-hole area of micropattern after depositing ZnO.

| Element | Element | Element | Atomic | Weight |
|---|---|---|---|---|
| number | symbol | name | conc. | conc. |
| 8 | O | Oxygen | 71.391 | 35.035 |
| 14 | Si | Silicon | 3.485 | 3.003 |
| 20 | Ca | Calcium | 7.491 | 9.209 |
| 22 | Ti | Titanium | 3.475 | 5.105 |
| 30 | Zn | Zinc | 0.799 | 1.602 |
| 40 | Zr | Zirconium | 2.182 | 6.106 |
| 41 | Nb | Niobium | 5.445 | 15.516 |
| 57 | La | Lanthanum | 5.732 | 24.424 |

TABLE 8
EDS of off-hole area of micropattern after depositing ZnO.

| Element | Element | Element | Atomic | Weight |
|---|---|---|---|---|
| number | symbol | name | conc. | conc. |
| 8 | O | Oxygen | 74.344 | 39.239 |
| 14 | Si | Silicon | 3.565 | 3.303 |
| 20 | Ca | Calcium | 7.268 | 9.610 |
| 22 | Ti | Titanium | 3.104 | 4.905 |
| 40 | Zr | Zirconium | 1.863 | 5.606 |
| 41 | Nb | Niobium | 5.160 | 15.816 |
| 57 | La | Lanthanum | 4.696 | 21.522 |

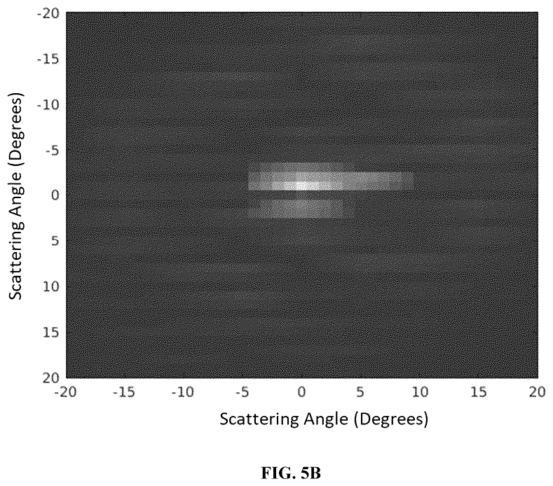

Optical performance was measured on the for the micropatterned glass including the deposited ZnO nanoparticles. FIGS. 5A-B illustrate 3D and 2D optical transmission spectra of the micropatterned glass including the deposited ZnO nanoparticles measured with 520 nm incident angle. The peaks that are observed in the spectra (most clearly seen in the left column FIG. 5A) come from diffraction effects.

### Example 3. Laser Treatment of Glass and Thermal Treatment to Form Micropattern

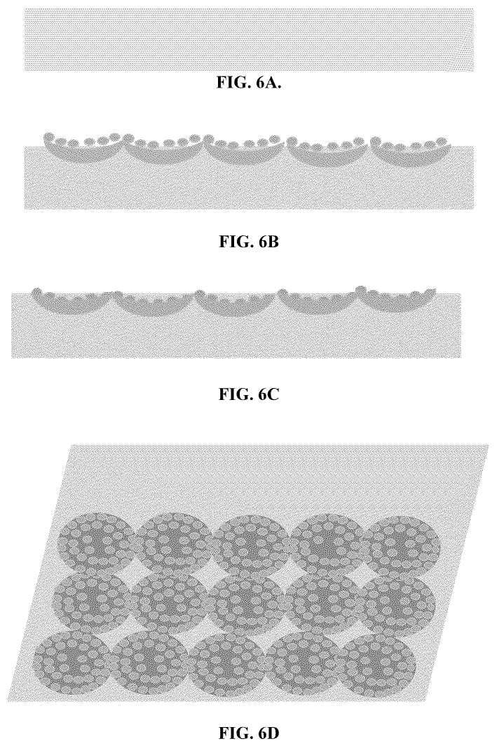

FIGS. 6A-D illustrate the fabrication processes used. A clean glass substrate (FIG. 6A) was patterned using laser ablation (FIG. 6B). After thermal treatment, a micro pattern gradient structure was observed (FIG. 6C). The thermal treatment can quench nanoparticles generated by laser ablation to form gradient structure. FIG. 6D shows a top view of the micro pattern gradient structure on glass. While the patterned substrates formed in Examples 1 and 2 included nanoparticles having a different index than the substrate onto which they are anchored, the present examples demonstrates in situ thermally quenched glass nanoparticles anchored to the holes in the glass substrate.

The laser treatment was performed at room temperature using a gaussian beam having a diameter of 3 microns to 12 microns, a wavelength of 355 to 1064 nm, a pulse energy of 10-30 microjoules, a repetition rate of 10-100 kHz, a scanning speed of 50 to 1500 mm/s, and laser power of 0.1-5 W (20%-50%).

The laser-patterned glass substrate was then placed immediately into an oven for 30 minutes at 400° C.

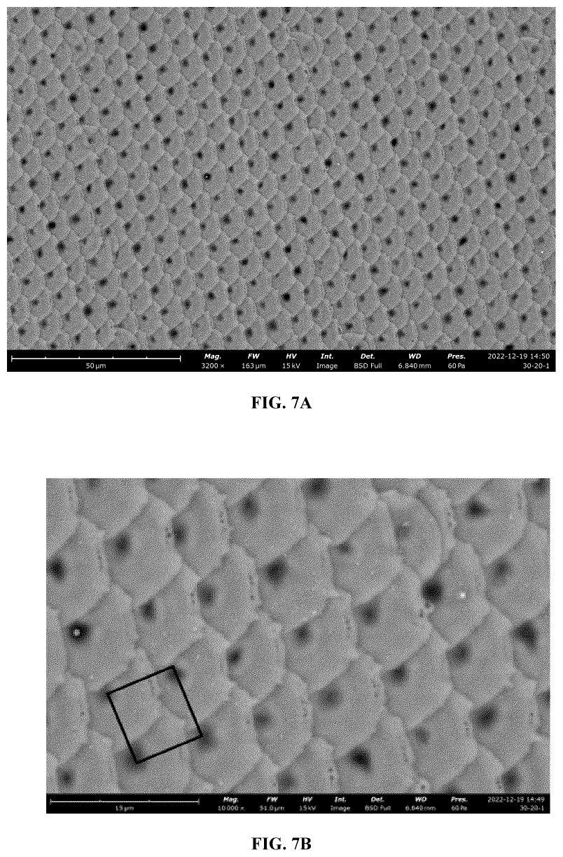

After laser ablation and thermal treatment, a micro pattern gradient structure on glass can be observed, as shown in FIG. 7A. FIG. 7B shows a high-resolution SEM image of micropattern gradient structure with a pitch of 7 micrometers (as illustrated by the overlaid square). The diameter and distance can be tuned by controlling laser power and stage feeding speed.

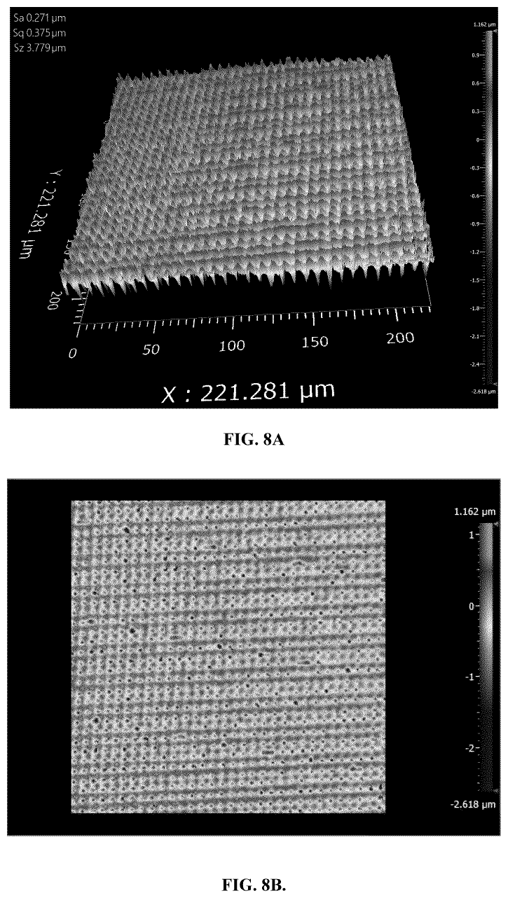

FIGS. 8A-B illustrate 3D and 2D top view interferometer images of the micropatterned gradient structure on glass. From the images, gradient morphologies patterned on the glass can be observed.

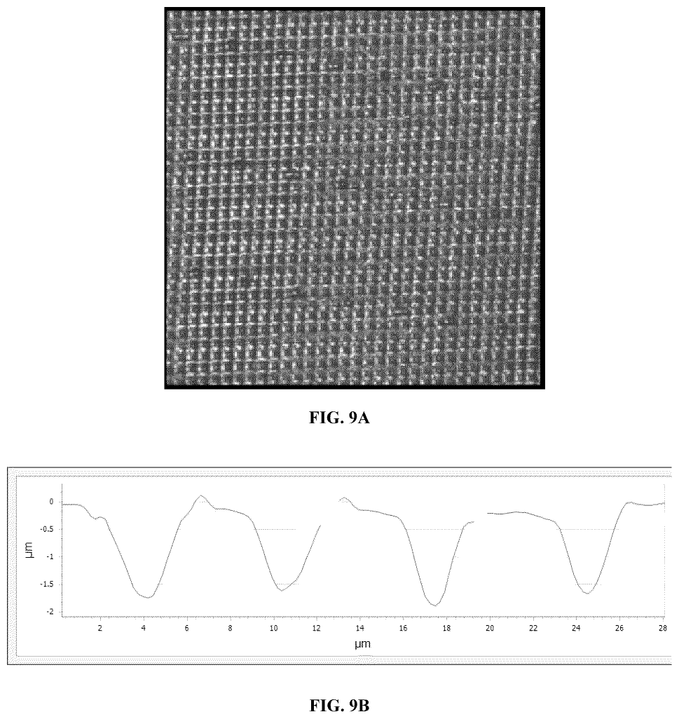

FIGS. 9A-B illustrate an intensity image of interferometer data of the micropattern gradient structure on glass, and profile a two-dimensional slice through the micropattern gradient area. The micropattern gradient structure had a pitch of 7 micrometers and a depth in a range of 1.5 to 1.8 micrometers. The texture dimension of micro pattern gradient structure is suitable for use as a beam splitter.

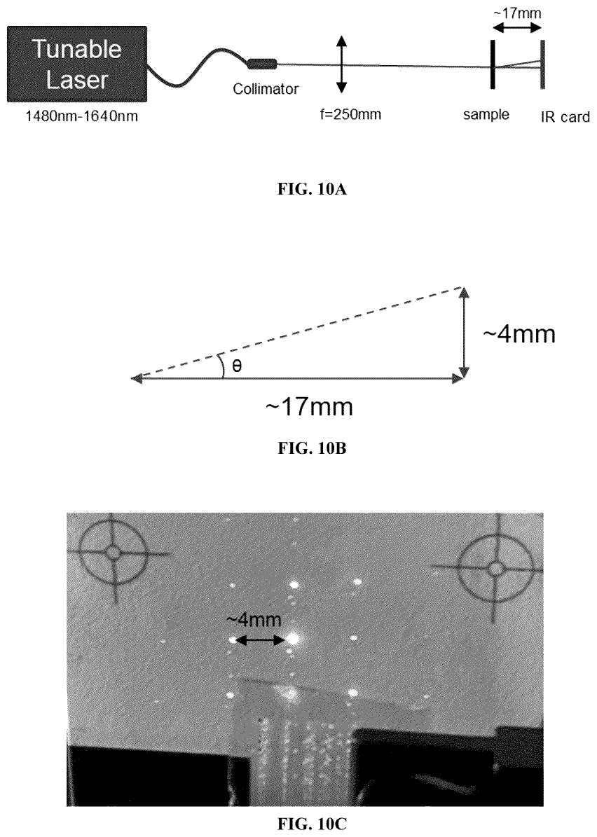

Optical performance has been measured on the micro pattern gradient structure on glass for beam splitter. According to the generalized Snell's law, the angle of split-beam can be obtained nₜ sin θₜ−nᵢ sin θᵢ=(λ/2π)*(dΦ/dr), where nᵢ (nₜ) represents the refractive index of the incident (refraction) medium, θᵢ (θₜ) is the incident (refraction) angle, λ is the vacuum wavelength of the light, and dΦ/dr is the phase gradient imparted along the micro surface. With the parameters λ=1550 nm and Γ=7000 nm (Γ=Δx), the angle of split beam can be obtained by θ=sin⁻¹(λ/Γ); θ=12.8; Δh/Γ=tan θ; Δh=1590 nm. FIG. 10A illustrates equipment used to measure optical diffraction pattern spectra. FIG. 10B illustrates an angle of split beam formed during optical diffraction pattern measurement. FIG. 10C shows the optical diffraction pattern spectra measured with 1480 to 1640 nm incident. The angle of split beam can be calculated as 13 degrees, which is consistent to the theoretical value of 12.8 degrees.

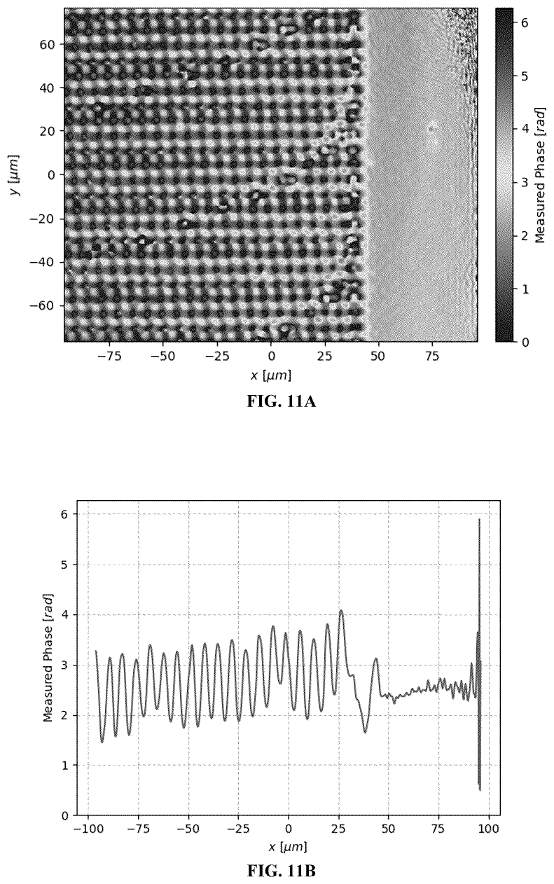

The phase profile, as illustrated in FIGS. 11A-B, was measured using off-axis digital holography setup shows micro patterned structure with the pitch of 7 um. Laser parameters and thermal treatment conditions can be optimized to improve the uniformity of micro gradient pattern structure. Furthermore, the micro pattern structure can be tuned to control the angle of split beam based on micropattern gradient structure formed on glasses.

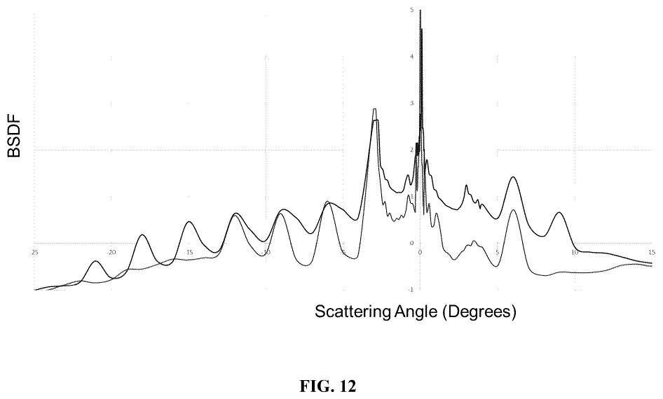

Following the laser treatment procedure described in this Example, two glass substrates were treated using the same scanning speed with different laser power (20% and 30%). FIG. 12 shows comparison of BSDF versus scattering angle at low-angle transmission, with the upper line corresponding to 30% power and the lower line corresponding to 20% power. The observed peaks come from diffraction effects. From the peaks, a micro pattern gradient structure with the pitch of 10 micrometers can be calculated, which is consistent with SEM measurements (not shown). The background of the spectra in FIG. 12 results from nanoparticles scattering generated by laser ablation. The intensity of background increased with increasing laser power (from 20% to 30%). Indeed, as shown, local minima in the BSDF (between peaks) for the example prepared with the laser at 30% power have amplitudes above 1 sr⁻¹ over a scattering angle range from −8° to 8°. This is not the case for the example prepared with the laser at 20% power. Increased nanoparticle density also is associated with peaks having increased angular widths. This demonstrates that the nanoparticles described herein can be used to provide diffuse beam splitters where diffraction peaks contrast less with background scattering, as compared with samples prepared without nanoparticles. It is believed that such an effect can be useful for various visual effects and/or for limiting the beam power at the angles associated with the diffraction peaks for various applications (e.g., where more diffuse illumination is needed). In view of this example, it is believed that the density of the nanoparticles can be increased with increasing laser power. Both nanoparticle density and distribution can be controlled and tuned by varying the laser conditions. The techniques described herein therefore provide a framework for controlling the shape and power of diffracted beams by enabling the precise tuning of BSDF by controlling the density and distribution of nanoparticles.

The terms and expressions that have been employed are used as terms of description and not of limitation, and there is no intention in the use of such terms and expressions of excluding any equivalents of the features shown and described or portions thereof, but it is recognized that various modifications are possible within the scope of the aspects of the present invention. Thus, it should be understood that although the present invention has been specifically disclosed by specific aspects and optional features, modification and variation of the concepts herein disclosed may be resorted to by those of ordinary skill in the art, and that such modifications and variations are considered to be within the scope of aspects of the present invention.

### Exemplary Aspects.

The following exemplary aspects are provided, the numbering of which is not to be construed as designating levels of importance:

Aspect 1 provides a patterned substrate comprising:
a substrate comprising a plurality of laser-ablated areas thereon arranged in the shape of a pattern, the laser-ablated areas each comprising a nanomaterial therein, wherein non-laser-ablated areas on the substrate have a lower concentration of the nanomaterial than the laser-ablated areas.

Aspect 2 provides the patterned substrate of Aspect 1, wherein the patterned substrate is an optical substrate.

Aspect 3 provides the patterned substrate of any one of Aspects 1-2, wherein the patterned substrate is optically transparent.

Aspect 4 provides the patterned substrate of any one of Aspects 1-3, wherein the patterned substrate is a diffractive optical waveguide, a beam splitter, a diffractive diffuser, or a combination thereof.

Aspect 5 provides the patterned substrate of any one of Aspects 1-4, wherein the patterned substrate is a beam splitter.

Aspect 6 provides the patterned substrate of any one of Aspects 1-5, wherein the substrate comprises glass, ceramic, silicon, quartz, or a combination thereof.

Aspect 7 provides the patterned substrate of any one of Aspects 1-6, wherein the substrate is flat.

Aspect 8 provides the patterned substrate of any one of Aspects 1-7, wherein non-laser-ablated areas of the substrate are substantially free of the nanomaterial.

Aspect 9 provides the patterned substrate of any one of Aspects 1-8, wherein the laser-ablated areas each comprise a pit, a trench, a polygon, an irregular shape, a line segment, a triangle, or a circle.

Aspect 10 provides the patterned substrate of any one of Aspects 1-9, wherein the laser-ablated areas each comprise a pit in the substrate, the pit comprising the nanomaterial therein.

Aspect 11 provides the patterned substrate of Aspect 10, wherein the pits comprising the nanomaterial have a diameter of 1 micron to 50 microns.

Aspect 12 provides the patterned substrate of any one of Aspects 10-11, wherein the pits comprising the nanomaterial have a diameter of 1 micron to 10 microns.

Aspect 13 provides the patterned substrate of any one of Aspects 10-12, wherein the pits comprising the nanomaterial have a depth of 0.1 micron to 10 microns.

Aspect 14 provides the patterned substrate of any one of Aspects 10-13, wherein the pits comprising the nanomaterial have a depth of 0.5 microns to 3 microns.

Aspect 15 provides the patterned substrate of any one of Aspects 10-14, wherein the pit comprises a coating of the nanomaterial therein.

Aspect 16 provides the patterned substrate of Aspect 15, wherein the coating of the nanomaterial has a substantially uniform thickness.

Aspect 17 provides the patterned substrate of any one of Aspects 15-16, wherein the coating of the nanomaterial has a thickness of 1 nm to 25 microns.

Aspect 18 provides the patterned substrate of any one of Aspects 15-17, wherein the coating of the nanomaterial has a thickness of 1 nm to 1000 nm.

Aspect 19 provides the patterned substrate of any one of Aspects 10-18, wherein the pit comprises the nanomaterial coated around inner edges of the pit such that the nanomaterial decreases the diameter of the laser-ablated pit.

Aspect 20 provides the patterned substrate of Aspect 19, wherein the pit has a pre-nanomaterial-addition diameter and/or depth that is 1 nm to 25 microns greater than a corresponding diameter and/or depth of the pit comprising the nanomaterial.

Aspect 21 provides the patterned substrate of any one of Aspects 19-20, wherein the pit has a pre-nanomaterial-addition diameter and/or depth that is 1 nm to 1000 nm greater than a corresponding diameter and/or depth of the pit comprising the nanomaterial.

Aspect 22 provides the patterned substrate of any one of Aspects 1-21, wherein the pattern comprises a spacing between the laser-ablated areas of no more than 100 microns.

Aspect 23 provides the patterned substrate of any one of Aspects 1-22, wherein the pattern comprises a spacing between the laser-ablated areas of 1 micron to 20 microns.

Aspect 24 provides the patterned substrate of any one of Aspects 1-23, wherein the pattern comprises a periodic pattern.

Aspect 25 provides the patterned substrate of any one of Aspects 1-24, wherein the pattern comprises a grid.

Aspect 26 provides the patterned substrate of any one of Aspects 1-25, wherein the nanomaterial comprises MgO, Fe₂O₃, V₂O₅, Al₂O₃, SiO₂, ZnO, ZrO₂, TiO₂, Ag, Au, Cu, or a combination thereof.

Aspect 27 provides the patterned substrate of any one of Aspects 1-26, wherein the nanomaterial comprises SiO₂, ZnO, ZrO₂, TiO₂, or a combination thereof.

Aspect 28 provides the patterned substrate of any one of Aspects 1-27, wherein the nanomaterial comprises crystallites, nanoparticles, or a combination thereof.

Aspect 29 provides the patterned substrate of Aspect 28, wherein the crystallites and/or nanoparticles have a diameter of 1 nm to 1,000 nm.

Aspect 30 provides the patterned substrate of any one of Aspects 28-29, wherein the crystallites and/or nanoparticles have a diameter of 1 nm to 500 nm.

Aspect 31 provides a patterned optical substrate comprising:
a glass substrate comprising a plurality of laser-ablated areas thereon arranged in the shape of a periodic pattern and having a spacing therebetween of 1 micron to 20 microns, the laser-ablated areas each comprising a pit in the substrate, the pit comprising a nanomaterial therein, wherein non-laser-ablated areas on the substrate have a lower concentration of the nanomaterial than the laser-ablated areas;
wherein the pit comprises the nanomaterial coated around inner edges of the pit such that the nanomaterial decreases the diameter of the laser-ablated pit, wherein the pit comprising the nanomaterial therein has a diameter of 1 micron to 50 microns.

Aspect 32 provides a method of making the patterned substrate of any one of Aspects 1-31, the method comprising:
laser-ablating a substrate to form a pattern thereon comprising a plurality of laser-ablated areas; and
exposing the substrate to a nanomaterial precursor to grow a nanomaterial in each laser-ablated area, to form the patterned substrate.

Aspect 33 provides a method of making the patterned substrate of any one of Aspects 1-31, the method comprising:
exposing a substrate comprising a plurality of laser-ablated areas arranged in the shape of a pattern to a nanomaterial precursor to grow a nanomaterial in each laser-ablated area, to form the patterned substrate.

Aspect 34 provides the method of Aspect 33, wherein each laser-ablated area comprises a pit, wherein the pit comprises the grown nanomaterial therein.

Aspect 35 provides the method of any one of Aspects 33-34, further comprising laser-ablating the substrate to form the plurality of laser-ablated areas on the substrate.

Aspect 36 provides the method of any one of Aspects 33-35, wherein the nanomaterial precursor comprises a material added to the laser-ablated substrate.

Aspect 37 provides the method of Aspect 36, wherein the nanomaterial precursor comprises a solution that forms the nanomaterial.

Aspect 38 provides the method of Aspect 37, wherein the nanomaterial precursor comprises a solution comprising a zinc salt, wherein the nanomaterial comprises ZnO.

Aspect 39 provides the method of any one of Aspects 37-38, wherein the nanomaterial precursor comprises a solution comprising ZrO₂.

Aspect 40 provides the method of any one of Aspects 33-39, wherein the nanomaterial precursor comprises a material produced by laser-ablating of the substrate.

Aspect 41 provides the method of Aspect 40, wherein the nanomaterial comprises SiO₂.

Aspect 42 provides the method of any one of Aspects 33-41, wherein the exposing the substrate to the nanomaterial precursor comprises thermally treating the laser-ablated substrate in the presence of the nanomaterial precursor to form the patterned substrate.

Aspect 43 provides the method of any one of Aspects 33-42, wherein the exposing the substrate to the nanomaterial precursor comprises adding the nanomaterial precursor to the laser-ablated substrate, and thermally treating the laser-ablated substrate having the nanomaterial precursor added thereto.

Aspect 44 provides the method of any one of Aspects 33-43, wherein the exposing the substrate to the nanomaterial precursor comprises thermally treating the laser-ablated substrate having the nanomaterial precursor formed by laser-ablating of the substrate thereon.

Aspect 45 provides the method of any one of Aspects 33-44, wherein the exposing the substrate to the nanomaterial precursor comprises spin-coating a solution of the nanomaterial precursor on the laser-ablated substrate, and thermally treating the spin-coated laser-ablated substrate.

Aspect 46 provides the method of any one of Aspects 33-45, wherein the exposing the substrate to the nanomaterial precursor comprises immersing the laser-ablated substrate in a solution comprising the nanomaterial precursor.

Aspect 47 provides the method of Aspect 46, wherein the immersing is performed at a temperature of 0° C. to 100° C.

Aspect 48 provides the method of any one of Aspects 46-47, wherein the immersing is performed at a temperature of 60° C. to 100° C.

Aspect 49 provides the method of any one of Aspects 46-48, wherein the immersing is performed for a duration of 1 minute to 5 days.

Aspect 50 provides the method of any one of Aspects 46-49, wherein the immersing is performed for a duration of 10 minutes to 1 hour.

Aspect 51 provides the method of any one of Aspects 33-50, wherein the exposing the substrate to the nanomaterial precursor comprises thermally treating the laser-ablated substrate having the nanomaterial precursor thereon.

Aspect 52 provides the method of Aspect 51, wherein the thermal treatment comprises thermally treating at a temperature of 100° C. to 1,000° C.

Aspect 53 provides the method of any one of Aspects 51-52, wherein the thermal treatment comprises thermally treating at a temperature of 200° C. to 600° C.

Aspect 54 provides the method of any one of Aspects 51-53, wherein the thermal treatment comprises thermally treating for a duration of 1 minute to 5 days.

Aspect 55 provides the method of any one of Aspects 51-54, wherein the thermal treatment comprises thermally treating for a duration of 10 minutes to 1 hour.

Aspect 56 provides the method of any one of Aspects 35-55, wherein the laser-ablating comprises using a beam shape that is gaussian, non-gaussian, multimode, or flat-top.

Aspect 57 provides the method of any one of Aspects 35-56, wherein the laser-ablating comprises using a beam shape that is gaussian.

Aspect 58 provides the method of any one of Aspects 35-57, wherein the laser-ablating comprises using a laser with a wavelength of 180 nm to 10.6 microns.

Aspect 59 provides the method of any one of Aspects 35-58, wherein the laser-ablating comprises using a laser with a wavelength of 355-1064 nm.

Aspect 60 provides the method of any one of Aspects 35-59, wherein the laser-ablating comprises using a laser with a repetition rate of 1 kHz to 10,000 kHz.

Aspect 61 provides the method of any one of Aspects 35-60, wherein the laser-ablating comprises using a laser with a repetition rate of 10 kHz to 100 kHz.

Aspect 62 provides the method of any one of Aspects 35-61, wherein the laser-ablating comprises using a laser with a power of 0.01 W to 100 W.

Aspect 63 provides the method of any one of Aspects 35-62, wherein the laser-ablating comprises using a laser with a power of 0.1 W to 10 W.

Aspect 64 provides the method of any one of Aspects 35-63, wherein the laser-ablating comprises using a laser with an energy of 1 microjoule to 1,000 microjoules.

Aspect 65 provides the method of any one of Aspects 35-64, wherein the laser-ablating comprises using a laser with an energy of 5 microjoule to 100 microjoules.

Aspect 66 provides the method of any one of Aspects 35-65, wherein the laser-ablating comprises using a laser with a speed of 1 mm/s to 10,000 mm/s.

Aspect 67 provides the method of any one of Aspects 35-66, wherein the laser-ablating comprises using a laser with a speed of 500 mm/s to 10,000 mm/s.

Aspect 68 provides the method of any one of Aspects 35-67, wherein the laser-ablating comprises using a laser with a beam diameter of 0.5 micron to 100 microns.

Aspect 69 provides the method of any one of Aspects 35-68, wherein the laser-ablating comprises using a laser with a beam diameter of 3 microns to 12 microns.

Aspect 70 provides a method of making a patterned substrate, the method comprising:
exposing a substrate comprising a plurality of laser-ablated areas arranged in the shape of a pattern, each laser-ablated area comprising a pit, to a nanomaterial precursor to grow a nanomaterial in each pit, to form the patterned substrate, wherein non-laser-ablated areas on the substrate have a lower concentration of the nanomaterial than the laser-ablated areas.

Aspect 71 provides a method of making a patterned substrate, the method comprising:
spin-coating a substrate comprising a plurality of laser-ablated areas arranged in the shape of a pattern, each laser-ablated area comprising a pit, with a solution comprising a nanomaterial precursor; and
thermally treating the spin-coated laser-ablated substrate to grow the nanomaterial in the pit of each laser-ablated area, to form the patterned substrate, wherein non-laser-ablated areas on the substrate have a lower concentration of the nanomaterial than the laser-ablated areas.

Aspect 72 provides a method of making a patterned substrate, the method comprising:
immersing a substrate comprising plurality of laser-ablated areas arranged in the shape of a pattern, each laser-ablated area comprising a pit, with a solution comprising a nanoparticle precursor, to grow the nanomaterial in the pit of each laser-ablated area, to form the patterned substrate, wherein non-laser-ablated areas on the substrate have a lower concentration of the nanomaterial than the laser-ablated areas.

Aspect 73 provides a method of making a patterned substrate, the method comprising:
laser-ablating a glass substrate to form a pattern thereon comprising a plurality of laser-ablated areas, each laser-ablated area comprising a pit; and
thermally treating the laser-ablated substrate and a nanoparticle precursor comprising a material produced during the laser-ablating of the substrate to grow a nanomaterial comprising SiO₂ in the pit of each laser-ablated area, to form the patterned substrate, wherein non-laser-ablated areas on the substrate have a lower concentration of the nanomaterial than the laser-ablated areas.

Aspect 74 provides the patterned substrate or method of any one or any combination of Aspects 1-73 optionally configured such that all elements or options recited are available to use or select from.

What is claimed is:

1. A patterned substrate comprising:
a substrate comprising a plurality of laser-ablated areas thereon arranged in the shape of a pattern, the laser-ablated areas each comprising a nanomaterial therein, wherein non-laser-ablated areas on the substrate have a lower concentration of the nanomaterial than the laser-ablated areas.

2. The patterned substrate of claim 1, wherein the patterned substrate is an optical substrate, wherein the patterned substrate is optically transparent.

3. The patterned substrate of claim 1, wherein the patterned substrate is a beam splitter.

4. The patterned substrate of claim 1, wherein the substrate comprises glass, ceramic, silicon, quartz, or a combination thereof.

5. The patterned substrate of claim 1, wherein non-laser-ablated areas of the substrate are substantially free of the nanomaterial.

6. The patterned substrate of claim 1, wherein the laser-ablated areas each comprise a pit in the substrate, the pit comprising the nanomaterial therein.

7. The patterned substrate of claim 6, wherein the pits comprising the nanomaterial have a diameter of 1 micron to 50 microns and a depth of 0.1 micron to 10 microns.

8. The patterned substrate of claim 1, wherein the laser-ablated areas comprise the nanomaterial coated thereon such that the nanomaterial decreases a size of the laser-ablated areas.

9. The patterned substrate of claim 1, wherein the pattern comprises a spacing between the laser-ablated areas of no more than 100 microns.

10. The patterned substrate of claim 1, wherein the nanomaterial comprises SiO₂, ZnO, ZrO₂, TiO₂, or a combination thereof.

11. The patterned substrate of claim 1, wherein the nanomaterial comprises crystallites, nanoparticles, or a combination thereof, wherein the crystallites and/or nanoparticles have a diameter of 1 nm to 1,000 nm.

12. A patterned optical substrate comprising:
a glass substrate comprising a plurality of laser-ablated areas thereon arranged in the shape of a periodic pattern and having a spacing therebetween of 1 micron to 20 microns, the laser-ablated areas each comprising a pit in the substrate, the pit comprising a nanomaterial therein, wherein non-laser-ablated areas on the substrate have a lower concentration of the nanomaterial than the laser-ablated areas;
wherein the pit comprises the nanomaterial coated around inner edges of the pit such that the nanomaterial decreases the diameter of the laser-ablated pit, wherein the pit comprising the nanomaterial therein has a diameter of 1 micron to 50 microns.

13. A method of making the patterned substrate of claim 1, the method comprising:
exposing a substrate comprising a plurality of laser-ablated areas arranged in the shape of a pattern to a nanomaterial precursor to grow a nanomaterial in each laser-ablated area, to form the patterned substrate.

14. The method of claim 13, further comprising laser-ablating the substrate to form the plurality of laser-ablated areas on the substrate.

15. The method of claim 13, wherein the nanomaterial precursor comprises a material produced by laser-ablating of the substrate, wherein the exposing the substrate to the nanomaterial precursor comprises thermally treating the laser-ablated substrate having the nanomaterial precursor formed by laser-ablating of the substrate thereon.

16. The method of claim 15, wherein the nanomaterial comprises SiO₂.

17. The method of claim 13, wherein the exposing the substrate to the nanomaterial precursor comprises adding the nanomaterial precursor to the laser-ablated substrate, and thermally treating the laser-ablated substrate having the nanomaterial precursor added thereto.

18. The method of claim 13, wherein the exposing the substrate to the nanomaterial precursor comprises:
spin-coating a solution of the nanomaterial precursor on the laser-ablated substrate, and thermally treating the spin-coated laser-ablated substrate; or
immersing the laser-ablated substrate in a solution comprising the nanomaterial precursor.

19. The method of claim 13, wherein the exposing the substrate to the nanomaterial precursor comprises thermally treating the laser-ablated substrate having the nanomaterial precursor thereon, wherein the thermal treatment comprises thermally treating at a temperature of 200° C. to 600° C. for a duration of 10 minutes to 1 hour.

20. The method of claim 14, wherein the laser-ablating comprises using a laser with a shape that is gaussian, a wavelength of 355 nm to 1064 nm, a repetition rate of 10 kHz to 100 kHz, a power of 0.1 W to 10 W, an energy of 5 microjoule to 100 microjoules, a speed of 500 mm/s to 10,000 mm/s, and a beam diameter of 3 microns to 12 microns.
